(19) United States
(12) Patent Application Publication
(10) Pub. No.: US 2021/0358926 A1
(43) Pub. Date: Nov. 18, 2021

(54) ANTI-FUSE UNIT

(71) Applicant: CHANGXIN MEMORY TECHNOLOGIES, INC., Hefei City (CN)

(72) Inventor: ChihCheng LIU, Hefei (CN)

(21) Appl. No.: 17/384,932

(22) Filed: Jul. 26, 2021

Related U.S. Application Data
(63) Continuation of application No. PCT/CN2021/079904, filed on Mar. 10, 2021.

(30) Foreign Application Priority Data
Apr. 8, 2020 (CN) 202010268396.3

(51) Int. Cl. H01L 27/112

(52) U.S. Cl. CPC H01L 27/11206

(57) ABSTRACT

An anti-fuse unit includes: an anti-fuse device; a transistor, located on a side of the anti-fuse device, electrically connected with the anti-fuse device, and forming a current path from the anti-fuse device to the transistor; and a first resistance structure and a second resistance structure, the first resistance structure and the second resistance structure being located in the current path.

### CROSS-REFERENCE TO RELATED APPLICATION

This application is a continuation application of International Patent Application No. PCT/CN2021/079904, filed on Mar. 10, 2021 and entitled “Anti-fuse Unit”, which claims priority to Chinese Patent Application No. 202010268396.3, filed on Apr. 8, 2020 and entitled “Anti-fuse Unit”. The contents of International Patent Application No. PCT/CN2021/079904 and Chinese Patent Application No. 202010268396.3 are hereby incorporated by reference in their entireties.

### TECHNICAL FIELD

The present disclosure relates to an anti-fuse unit.

### BACKGROUND

An anti-fuse device includes an upper electrode, a lower electrode and an anti-fuse dielectric layer between the upper electrode and the lower electrode. When the anti-fuse device is not programmed, a resistance of the anti-fuse device may reach a level of MΩ or even a level of GΩ. After the anti-fuse is programmed through a programmed voltage between the upper electrode and the lower electrode, the resistance of the anti-fuse device will drop significantly, generally by more than two orders of magnitude, to a level of MΩ or even less comparing with that of an unprogrammed anti-fuse device.

### SUMMARY

According to a plurality of embodiments, a first aspect of the present application provides an anti-fuse unit, including:

an anti-fuse device;

a transistor, located on a side of the anti-fuse device, electrically connected with the anti-fuse device, and forming a current path from the anti-fuse device to the transistor; and

a first resistance structure and a second resistance structure, the first resistance structure and the second resistance structure being located in the current path.

Electrical connection electrical connection.

Details of one or more embodiments of the present application will be proposed in the following accompanying drawings and descriptions. Other features and advantages of the present application will become apparent from the descriptions, the accompanying drawings and the claims.

### BRIEF DESCRIPTION OF THE DRAWINGS

To describe in the technical solutions of the embodiments of the present application more clearly, the following briefly introduces the accompanying drawings required in the embodiments. Apparently, the accompanying drawings in the following description show only some embodiments of the present application, and a person of ordinary skill in the art may derive other drawings from these accompanying drawings without creative efforts.

FIG. 1 is a schematic cross-sectional view of an anti-fuse unit according to an embodiment of the present disclosure.

FIG. 2 is a top view of an anti-fuse unit according to an embodiment of the present disclosure.

List of Reference Numerals: 10, anti-fuse device; 101, first gate dielectric layer; 102, first gate electrode; 103, anti-fuse injection layer; 20, transistor; 201, second gate dielectric layer; 202, second gate electrode; 203, drain electrode; 204, source electrode; 30, first resistance structure; 40, second resistance structure; 50, third resistance structure; 60, substrate; 70, shallow trench isolation structure.

### DETAILED DESCRIPTION

An existing anti-fuse unit includes an anti-fuse device and a selection transistor. However, a parasitic resistance value on a current path from a programmed voltage through the anti-fuse device and the selection transistor to the ground is large. Due to existence of divided voltages on these parasitic resistors, a size of the programmed voltage is affected during programming Therefore, under a condition of the same programmed voltage, the larger the parasitic resistance is, the less likely the anti-fuse device is to be broken down.

In order to understand the present disclosure conveniently, a more complete description of the present disclosure will be given below with reference to the relevant accompanying drawings. However, the present disclosure may be realized in many different forms and is not limited to the embodiments described herein. Rather, the purpose of providing these embodiments is to make disclosed contents of the present disclosure more thorough and comprehensive.

Unless otherwise defined, all technical and scientific terms used herein have the same meaning as would normally be understood by those of skill in the art of the present disclosure. Terms used herein in the specification of the present disclosure are for a purpose of describing specific embodiments only and are not intended to limit the present disclosure. The term “and/or” used herein includes any and all combinations of one or more related listed items.

In the description of the present disclosure, it is necessary to understand that orientation or position relations indicated by terms “upper”, “lower”, “vertical”, “horizontal”, “inside” and “outside” are based on methods or position relations shown in the accompanying drawings only for describing the present disclosure conveniently and simplifying the description of the present disclosure, rather than indicating or implying that devices or elements referred to must have a particular orientation, be constructed and operated in a particular orientation and shall not be construed as a limitation of the present disclosure.

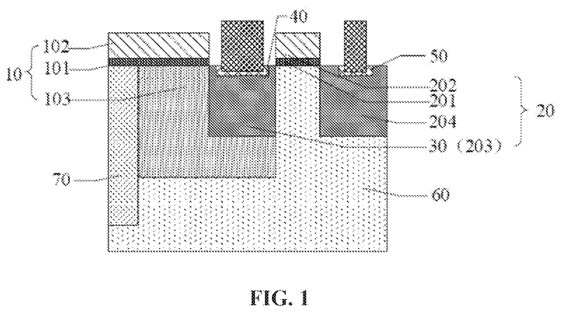

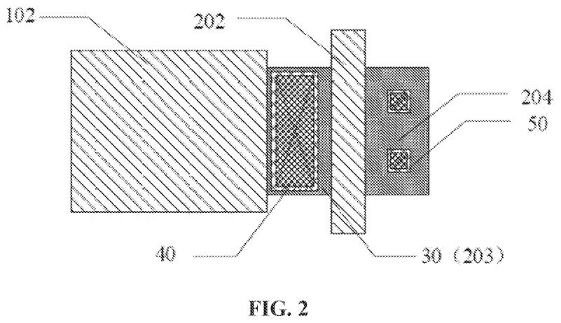

As shown in FIGS. 1 and 2, the present disclosure provides an anti-fuse unit, including an anti-fuse device 10 and a transistor 20. The transistor 20 is located on a side of the anti-fuse device 10, is electrically connected with the anti-fuse device 10, and forms a current path from the anti-fuse device 10 to the transistor 20. The current path includes a first resistance structure 30 and a second resistance structure 40.

A substrate 60 is provided. The substrate 60 may be a semiconductor substrate or a doped well, such as a monocrystalline silicon substrate, a monocrystalline germanium substrate and the like. In an optional embodiment, a shallow trench isolation structure 70 is formed in the substrate 60, and a doping type of the substrate 60 may be a P type.

In an optional embodiment, the anti-fuse device 10 includes a first gate dielectric layer 101 formed on an upper surface of the substrate 60, a first gate electrode 102 formed on an upper surface of the first gate dielectric layer 101 and an anti-fuse injection layer 103 in the substrate 60. A material of the first gate dielectric layer 101 may be one or a combination of high-K dielectric materials such as silicon oxide, silicon nitride, silicon oxynitride, zirconium oxide, hafnium oxide and the like. A material of the first gate electrode 102 may be at least one of polycrystalline silicon, titanium, copper, tungsten, metal silicides or other conductive materials. The anti-fuse injection layer 103 may be formed by means of ion injection, and a doping type of the anti-fuse injection layer 103 is contrary to the doping type in an active region and may be N-type doping.

The transistor 20 includes a second gate dielectric layer 201 formed on the upper surface of the substrate 60, a second gate electrode 202 formed on an upper surface of the second gate dielectric layer 201, a source electrode 204 and a drain electrode 203. The drain electrode 203 is the first resistance structure 30, and the drain electrode 203 and the first resistance structure 30 are a doping region formed in the substrate 60. A material of the second gate dielectric layer 201 may be one or a combination of high-K dielectric materials such as silicon oxide, silicon nitride, silicon oxynitride, zirconium oxide, hafnium oxide and the like. A material of the second gate electrode 202 may be at least one of polycrystalline silicon, titanium, copper, tungsten, metal silicides or other conductive materials. The source electrode 204 and the drain electrode 203 are formed in the substrate 60, and may be formed by means of ion injection. In other optional embodiments, a thickness of the first gate dielectric layer 101 is less than or equal to a thickness of the second gate dielectric layer 201, the thickness of the first gate dielectric layer 101 may range from 2 nm to 3 nm, such as 2 nm, 2.5 nm or 3 nm, and the thickness of the second gate dielectric layer 201 may range from 3 nm to 4 nm, such as 3 nm, 3.5 nm or 4 nm.

The first resistance structure 30 is connected in parallel with the second resistance structure 40 in the current path. In an optional embodiment, a resistance value of the second resistance structure 40 is less than a resistance value of the first resistance structure 30.

In an optional embodiment, the first resistance structure 30 is a heavily doped region, and may be N-type heavily doped. A doping concentration of the first resistance structure 30 may range from 1e20 to 5e21 cm⁻³, the first resistance structure 30 may be doped through As doping, an ion injection energy for the As doping may be comprised between 20 keV and 50 keV, and an injection dose for the As doping may be comprised between 1e15 and 5e15 cm⁻². In an optional embodiment, the second resistance structure 40 is a metal semiconductor contact region which is a metal silicide, and the metal silicide is embedded in the first resistance structure 30.

The second resistance structure 40 may be formed by following steps. The upper surface of the substrate 60 is etched to form a groove, and a metal pillar is formed in the groove, where the metal pillar is embedded in the first resistance structure 30. During an annealing process, the metal pillar reacts with the first resistance structure 30 to form a metal silicide, which is the second resistance structure 40. The second resistance structure 40 surrounds a portion of the metal pillar embedded in the first resistance structure 30.

The anti-fuse injection layer 103 is electrically connected with the first resistance structure 30 and the second resistance structure 40. The second gate electrode 202 of the transistor 20 is electrically connected with the first resistance structure 30 and the second resistance structure 40. After the first gate dielectric layer 101 is broken down, a current flows through a channel formed by an anti-fuse ion injection region, the first resistance structure 30, the second resistance structure 40, and the transistor 20, and reaches the drain electrode 203 of the transistor 20. The first resistance structure 30 is connected in parallel with the second resistance structure 40 between the first gate electrode 102 and the second gate electrode 202, so that resistance of the current path from the first gate electrode 102 to the second gate electrode 202 is reduced.

In an optional embodiment, the anti-fuse unit further includes a third resistance structure 50. The third resistance structure 50 is a metal semiconductor contact region which is a metal silicide, and the metal silicide is embedded in the source electrode 204.

The third resistance structure 50 may be formed by the following steps. The upper surface of the substrate 60 is etched to form a groove, and a metal pillar is formed in the groove, where the metal pillar is embedded in the source electrode 204. During an annealing process, the metal pillar reacts with the source electrode 204 to form a metal silicide, which is the third resistance structure 50. The third resistance structure 50 surrounds a portion of the metal pillar embedded in the first resistance structure 30.

In conclusion, according to the above anti-fuse unit, after the first gate dielectric layer 101 is broken down, the current flows through the current path to the drain electrode 203 of the transistor 20. In this process, the first resistance structure 30, the second resistance structure 40 and the third resistance structure 50 reduce the resistance of the current path, achieve a large breakdown current, and improve the performance of the anti-fuse unit.

Various technical features in the foregoing embodiments may be randomly combined. For ease of simple description, not all possible combinations of various technical features in the foregoing embodiments are described. However, as long as the combinations of these technical features do not contradict, they should be regarded as falling within the scope of the present specification.

The foregoing embodiment merely describes several implementation manners of the disclosure particularly in more detail, but it cannot be thus understood as limitations to the patent scope of the disclosure. It should be noted that a person of ordinary skill in the art may further make several variations and improvements without departing from the conception of the present invention, and all these fall within the protection scope of the disclosure. Therefore, the patent protection scope of the disclosure should be subject to the appended claims.

1. An anti-fuse circuit, comprising:
an anti-fuse device;
a transistor, located on a side of the anti-fuse device, electrically connected with the anti-fuse device, and forming a current path from the anti-fuse device to the transistor; and
a first resistance structure and a second resistance structure, the first resistance structure and the second resistance structure being located in the current path.

2. The anti-fuse circuit of claim 1, wherein the first resistance structure is connected in parallel with the second resistance structure.

3. The anti-fuse circuit of claim 2, wherein a resistance value of the second resistance structure is less than a resistance value of the first resistance structure.

4. The anti-fuse circuit of claim 3, wherein the first resistance structure is a heavily doped region.

5. The anti-fuse circuit of claim 4, wherein a doping concentration of the first resistance structure ranges from 1e20 to 5e21 cm⁻³, the first resistance structure is doped through As doping, an ion injection energy for the As doping is comprised between 20 keV and 50 keV, and an injection dose for the As doping is comprised between 1e15 and 5e15 cm⁻².

6. The anti-fuse circuit of claim 4, wherein the second resistance structure is a metal semiconductor contact region.

7. The anti-fuse circuit of claim 6, wherein the metal semiconductor contact region forms a metal silicide, and the metal silicide is at least partially embedded in the heavily doped region.

8. The anti-fuse circuit of claim 1, wherein the anti-fuse device comprises a first gate electrode, a first gate dielectric layer and an anti-fuse injection layer, and the anti-fuse injection layer is electrically connected with the first resistance structure and the second resistance structure.

9. The anti-fuse circuit of claim 8, wherein the transistor comprises a second gate electrode, a second gate dielectric layer, a source electrode and a drain electrode, and the first resistance structure is the drain electrode.

10. The anti-fuse circuit of claim 9, wherein the second gate electrode is electrically connected with the first resistance structure and the second resistance structure.

11. The anti-fuse circuit of claim 9, wherein a thickness of the first gate dielectric layer is less than or equal to a thickness of the second gate dielectric layer.

12. The anti-fuse circuit of claim 1, further comprising a third resistance structure, wherein the third resistance structure is electrically connected with the transistor, and the third resistance structure is located in the current path.

13. The anti-fuse circuit of claim 12, wherein a type of the third resistance structure and a type of the second resistance structure are the same.

14. The anti-fuse circuit of claim 1, wherein the anti-fuse device, the transistor, the first resistance structure and the second resistance structure are located in a P-type well.

15. The anti-fuse circuit of claim 8, wherein a material of the first gate dielectric layer is one or a combination of silicon oxide, silicon nitride, silicon oxynitride, zirconium oxide, hafnium oxide and the like.

16. The anti-fuse circuit of claim 8, wherein a material of the first gate electrode is at least one of polycrystalline silicon, titanium, copper, tungsten or metal silicides.

17. The anti-fuse circuit of claim 9, wherein a material of the second gate dielectric layer is one or a combination of silicon oxide, silicon nitride, silicon oxynitride, zirconium oxide and hafnium oxide.

18. The anti-fuse circuit of claim 9, wherein a material of the second gate electrode is at least one of polycrystalline silicon, titanium, copper, tungsten or metal silicides.

19. The anti-fuse circuit of claim 9, wherein a thickness of the first gate dielectric layer is less than or equal to a thickness of the second gate dielectric layer.

20. The anti-fuse circuit of claim 19, wherein a thickness of the first gate dielectric layer ranges from 2 nm to 3 nm, and a thickness of the second gate dielectric layer ranges from 3 nm to 4 nm.
